(19) United States
(12) Patent Application Publication
(10) Pub. No.: US 2011/0122587 A1
(43) Pub. Date: May 26, 2011

(54) FLEXIBLE CIRCUIT STRETCHING

(76) Inventors: Stephen R. Deming, San Jose, CA (US); Kevin von Essen, San Jose, CA (US); Andreas Bibl, Los Altos, CA (US); John A. Higginson, Santa Clara, CA (US); Micheal Rocchio, Hayward, CA (US)

(21) Appl. No.: 12/991,890

(22) PCT Filed: Apr. 30, 2009
(86) PCT No.: PCT/US09/42375

§ 371 Date: Feb. 3, 2011

Related U.S. Application Data
(60) Provisional application No. 61/055,119, filed on May 21, 2008.

(51) Int. Cl. H05K 1/18; H01L 21/58; H05K 3/00

(52) U.S. Cl. 361/749; 438/125; 29/729; 29/829; 257/E21.505

(57) ABSTRACT

A method of connecting electrical components and an electronic device formed using this method are disclosed. This method includes stretching a first substrate with a plurality of conductive traces to form a stretched substrate where at least one increased pitch (a spacing between two conductive traces plus a width of one conductive trace) is not greater than 40 microns; and electrically connecting the conductive traces on the first substrate to conductive traces on a second substrate. A device by which this method can be implemented is also disclosed, which includes a base, and platforms and stretchers mounted to the base that are configured to pull opposite ends of the first substrate to align the conductive traces thereon with the conductive traces on the second substrate.

### BACKGROUND

The following description relates to connecting circuits formed on a flexible substrate to circuits on another substrate.

Flexible circuits can be used to make simple and reliable electronic interconnections between devices. A flexible circuit can replace a series of individual wires or printed circuit boards and solder that would otherwise be used to connect electronic components together. These flexible circuits are formed with conductive traces for making the electrical connections disposed on a flexible substrate. The conductive traces can be fabricated with a small pitch (the pitch represents a width of a conductive trace plus the spacing between the conductive trace and an adjacent conductive). The circuits are formed of a flexible material so that the circuits can be used in locations or applications that other circuitry, such as a rigid or semi-rigid circuit, could not be used. Flexible circuits may be of benefit in devices that require tight tolerance or fine-line circuits, such as in medical devices or printing devices.

### SUMMARY

A method of connecting electrical components is described. In one aspect, the method includes disposing a first substrate with a plurality of conductive traces for comparison with a plurality of conductive traces on a second substrate, and stretching the first substrate to form a stretched substrate. The traces of the stretched substrate are aligned with the corresponding traces of the second substrate, and a pitch of the traces on the stretched substrate is not greater than 40 microns.

Implementations can include one or more of the following features. Some of the traces on the stretched substrate can be electrically connected to some of the traces on the second substrate or some traces on a third substrate. Anisotropic conductive film (ACF) can be applied to the first substrate for electrically connecting the first and second substrates. Optionally, heating and applying pressure to the first substrate can be used for such electrically connecting process. The first substrate can be a flexible circuit and the second substrate can be a silicon die.

Stretching the first substrate can include pulling a first end of the first substrate while fixing a second end of the first substrate until a first conductive trace on the first substrate aligns with a corresponding first conductive trace on the second substrate; and pulling the second end of the first substrate while fixing the first end of the first substrate until a second conductive trace on the first substrate aligns with a corresponding second trace on the second substrate. Stretching can further include pulling a center of the first substrate, causing the first substrate to flatten. Such a stretching process can be iterated until the conductive traces on the first substrate match up with the corresponding conductive traces on the second substrate.

A portion of suitable material can be attached to each of a first end and a second end of the first substrate. The portion can have one or more openings for receiving a fastener. After stretching the first substrate, the attached portion can be removed from the first end and the second end.

In some implementations, stretching increases a length of the first substrate by between 0.01% to 5%. In various implementations, the increase is less than 2% or even less than 1%. Alternatively, stretching increases the length of the first substrate by at least 1 micron, e.g., at least 6 to 10 microns. The pitch of the conductive traces on the first substrate before stretching can be 40 microns to less, such as 36 microns or less. In some embodiments, the pitch of the conductive traces can be approximately 10 microns. In another aspect, this application features an electronic device formed by applying the method described above. Such a device includes a first substrate with a plurality of conductive traces thereon and at least one increased pitch on the stretched substrate is not greater than 40 microns. The device further includes a second substrate with the conductive traces thereon aligned and in electrical contact with conductive traces on the first substrate. In various implementations, the first substrate is a flexible circuit and the second substrate is a silicon die.

A device for stretching a substrate is also disclosed herein. The device includes a base, a first platform mounted on the base for receiving a first substrate thereon, a second platform mounted on the base for receiving a second substrate thereon, and a first stretcher and a second stretcher disposed near a first side and a second side of the first platform respectively, and mounted onto the base. The first side and the second side are opposite sides of the first platform. The first stretcher and the second stretcher are configured to move over the base in increments of millimeters or less to pull the first substrate from a first end and a second end of the first substrate, respectively, along a first axis in opposite directions, such that the first substrate is stretched to align a plurality of conductive traces thereon with corresponding conductive traces on the second substrate.

Implementations can include one or more of the following features. The first stretcher and the second stretcher can include at least one of a post, pin, a bolt, a clamp, a screw, a tack, or a nail, to temporarily secure a first end and a second end of the first substrate, respectively. The first stretcher and the second stretcher each have a knob coupled thereto, and the knob can be rotated to move the first stretcher and the second stretcher, respectively. The second platform can include at least one of a pin, a bolt, a clamp, a screw, a tack, screw or a nail, to secure the second substrate supported thereon.

The device can include a third stretcher disposed near a third side of the first platform, and mounted onto the base. The third stretcher is configured to move over the base in increments of millimeters or less to pull a center portion along a second axis that is orthogonal to the first axis, such that the first substrate can be stretched along the second axis. The third stretcher can include a clamp to temporarily secure a center portion of the first substrate.

The device can further include an x-axis adjust mounted onto the base and configured to move the first platform along an axis orthogonal to the first axis for carrying the first substrate towards and away from the second platform. The device can further include a y-axis adjust mounted onto the base and configured to move the first platform along the first axis for carrying the first substrate sideways along the second platform. A theta-adjust can also be included, which is mounted onto the base and configured to rotate the first platform for carrying the first substrate to an appropriate angle for stretching. The theta-adjust rotates the first platform relative to the second platform.

The device can additionally include a microscope for magnifying a view of the first substrate. The microscope can include a camera, and a display electronically connected with the camera such that the camera can transmit an image captured from the microscope to the display to show the image.

Implementations of the devices and methods described herein may include one or more of the following advantages. A smaller dimension for a pitch, e.g., 40 microns or less, is sometimes desirable in certain electronic applications. However, because flexible circuits are generally made of plastic, such as a polyimide film, e.g., Kapton®, which tends to shrink at an elevated temperature, a final size of a pitch or flexible circuits is difficult to control. Use of the techniques described herein can facilitate properly matching traces and connectors on the circuit and a component, as well as allow use of finer pitched flexible circuits over longer lengths than were previously possible.

Details of one or more implementations are set forth in the accompanying drawings and the description below. Other features and advantages may be apparent from the description and drawings, and from the claims.

### DRAWING DESCRIPTIONS

These and other aspects will now be described in detail with reference to the following drawings.

FIGS. 1A and 1B are schematic illustrations of a top view of a flexible circuit with integrated circuits mounted thereon, and an enlarged top view of a representative portion of the flexible circuit, respectively.

FIGS. 2A and 2B are schematic illustrations of a top view of a representative section of the flexible circuit after being stretched and an enlarged top view of selected traces.

FIGS. 3-4 are flow diagrams of exemplary processes for stretching a first substrate with a plurality of conductive traces to align with a plurality of conductive traces on a second substrate.

FIG. 5 is a perspective view of a stretching device for stretching a first substrate to align conductive traces thereon with corresponding conductive traces on a second substrate.

Like reference symbols in the various drawings indicate like elements.

### DETAILED DESCRIPTION

Flexible circuits can provide a way to send electrical signals to an electronic component while simultaneously facilitating production of a device including the component by eliminating multiple single wires or rigid circuit supports. Where an electronic component is mounted directly on a flexible plastic substrate, the assembly is known as a flex circuit or flexible electronics.

One exemplary use of a flexible circuit is for sending signals to a microelectromechanical (MEMS) device that includes a number of actuators. Specific MEMS and thermal devices are drop-on-demand ink jet print heads. An exemplary MEMS device constructed on a silicon die is described in U.S. Pat. No. 5,265,315, and a semiconductor printhead unit is described in U.S. Publication No. US-2005-0099467-A1, which are incorporated herein by reference. The actuators for a printhead can be piezoelectric actuators or thermal actuators, depending on the device type. A single die includes a number of jetting structures, such as 16, 128, or more jetting structures, each having a fluid path and an associated actuator. The signals carried by the flexible circuit are used to individually drive or activate each of the actuators on the device.

When the actuator is activated, fluid is forced through the fluid path and out a nozzle. As MEMS fabrication technology has developed, the spacing between individual jetting structures has become smaller. Similarly the spacing of actuators and the conductive traces to reach the actuators has decreased. Often, any flexible circuits or circuits that are connected to the device have conductive lines that match the pitch of the traces to ensure that each actuator receives the appropriate signal. However, matching conductive lines or traces with very fine pitches becomes difficult, particularly because of manufacturing tolerances and material susceptibility to temperature changes. Forming a flexible circuit with traces that are closer together than a pitch of conductive lines on a substrate such as a silicon die, or other device, and stretching the flexible circuit so that the pitch of the traces on the flexible circuit matches the pitch of the lines on the substrate, can compensate for these potential manufacturing obstacles.

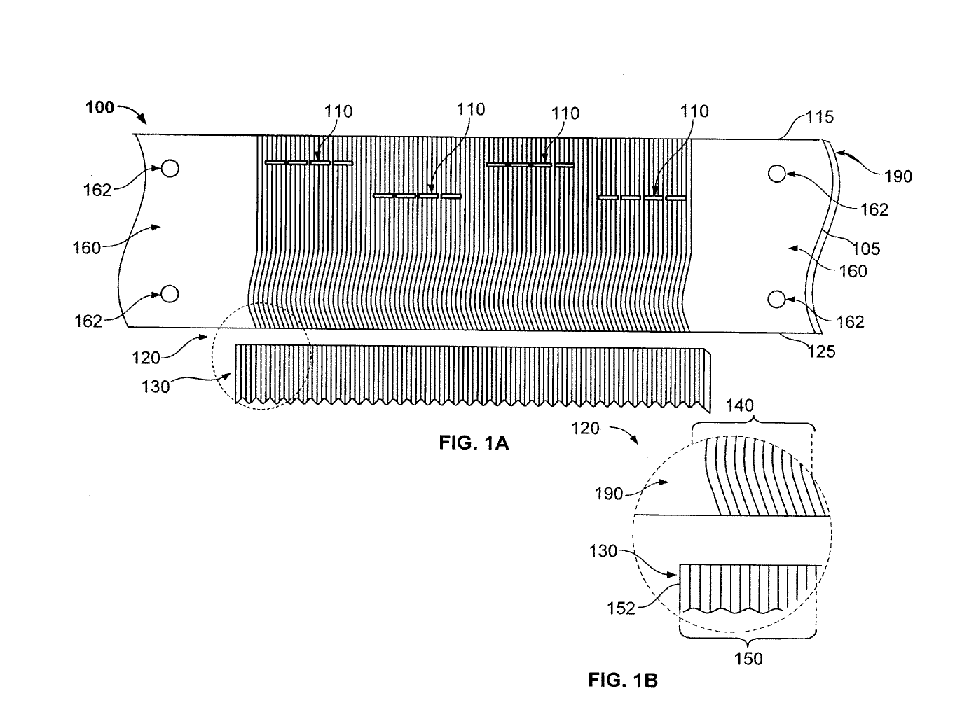

FIG. 1A is a schematic illustration of a top view of a flexible electronics 100. The flexible electronics 100 can include a flexible circuit 190 which has a flexible, e.g., bendable and stretchable, polymer sheet 105 on which conductive traces 140 are formed. The flexible electronics 100 can further include Integrated circuit (IC) chips 110 that are mounted on the flexible circuit 190. FIG. 1B is an enlarged top view of a representative section 120 of the flexible circuit 190. The conductive traces 140 formed on the polymer sheet 105 are in electrical connection with the integrated circuits 110. The flexible electronics 100 shown in FIGS. 1A and 1B is merely one embodiment of a flexible circuit with connected IC chips and serves only for illustrative purposes. Different embodiments of a flexible circuit can be used with the techniques described herein.

In one embodiment, when used with a substrate (e.g. silicon die) 130, the flexible circuit 190 includes external connectors (not shown in FIG. 1) along one edge 115 to connect the flexible circuit 190 to a source of signals, such as a processor. The opposite edge 125 of the flexible circuit 190 can be connected to the substrate 130 that forms a MEMS device. The integrated circuits 110 are mounted on the flexible circuit 190 to receive input signals from the external connectors and to generate output drive signals. The output drive signals are transmitted to the substrate 130 to selectively eject ink drops from specific nozzles, for example, by selectively firing corresponding actuators in the printhead. The integrated circuits 110 are connected to conductive traces 140. As shown in FIG. 1, the conductive traces 140 are distributed substantially evenly, with a uniform pitch, on the flexible circuit 190. In particular, the conductive traces 140 can have uniform pitch near the edges of the flexible circuit 190 that are to be connected to other components. However, the conductive traces 140 can be spaced other than evenly. The conductive traces 140 on the flexible circuit 190 can be made of metal, oxide, or other conductive materials that transmit electronic signals. In various implementations, the number of the conductive traces 140 on the flexible circuit 190 is 1,024.

The polymer sheet 105 of the flexible circuit 190 is formed of a flexible material that is not prone to breaking or cracking over time, such as plastic, polyester or polyimide, e.g., DuPont™ Kapton® materials. However, plastic tends to change in size and can shrink when the flexible circuit 190 is at a raised temperature. Thus, a final size of the flexible circuit 190 is difficult to control. Rather than attempting to control the final size of the flexible circuit 190 or the spacing between traces on the flexible circuit 190, the flexible circuit is made to have traces with a pitch similar to that of the traces on the device to which the flexible circuit 190 will be connected, e.g., the substrate 130. The flexible circuit 190 is then stretched before being bonded to the substrate 130. The length of the flexible circuit 190 (along the edge with the traces) after stretching is at least 0.01% greater than its original length. Alternatively, the stretching increases the length of the flexible circuit 190 along the edge with the traces by at least one-third, e.g., by at least half, of the width of a trace, e.g., by at least 6 to 10 microns for traces of about 20 micron width. The original pitch of the conductive traces 140 on the flexible circuit 190 can be approximately 40 microns or less, e.g., 36 microns to less. In some embodiments, the original pitch can be approximately 10 microns, e.g., 5 microns for the trace width and 5 microns for spacing between traces. The stretching may increase the length of the flexible circuit 190 by at least approximately 1 micron, e.g., at least about 2 microns, for traces of about 5 micron width.

As shown in the enlarged view of FIG. 1B, the conductive traces 140 on the flexible circuit do not initially align with corresponding conductive traces 150 on the substrate 130. For example, the first conductive trace 142 on the flexible circuit 190 does not match up with or align with the first conductive trace 152 on the substrate 130, even if the remaining traces on the flexible circuit 190 are aligned with traces on the substrate 130. After stretching the flexible circuit 190 to align corresponding conductive traces 140 on the flexible circuit 190 with conductive traces 150 on the substrate 130, the flexible circuit 190 is bonded to the substrate 130, as described further below.

The substrate 130 can be a part of or integrated into, for example, a MEMS silicon die, as the printhead described in Hoisington, et al., U.S. Pat. No. 5,265,315, which is incorporated herein by reference. The multiple conductive traces 150 on the substrate 130, as with the conductive traces 140 on the flexible circuit 190, can include metal, oxide, or other conductive materials that can transmit electronic signals. In various implementations, the number of the multiple conductive traces 150 on the substrate 130 is also 1,024, the same as the number of the conductive traces on the flexible circuit 190.

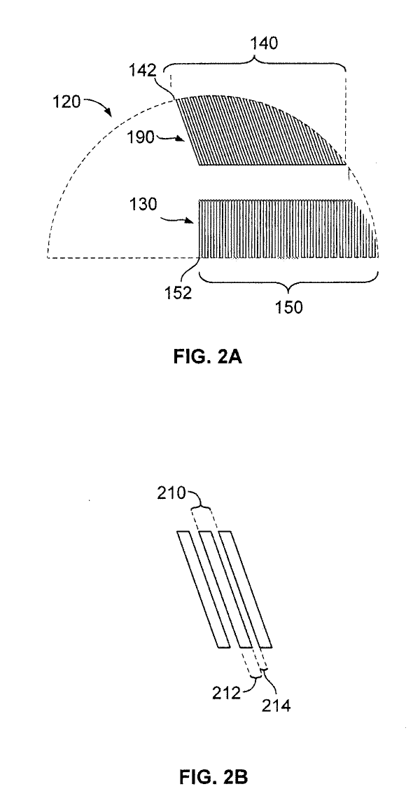

FIGS. 2A and 2B are schematic illustrations of a top view of the representative section 120 of the flexible circuit 190 after being stretched, and an enlarged view of few selected traces, respectively. Typically, an initial length of the flexible circuit 190 is less than 5% less than an after-stretching length of the flexible circuit 190. Alternatively, the stretching increases the length of the flexible circuit 190 by at least 6 to 10 microns. An original pitch of the conductive traces 140 on the flexible circuit 190 is approximately 40 microns or less, e.g., 36 microns to less, which depends on the material used to form the flexible circuit 190. In some embodiments, the original pitch of the conductive traces 140 is approximately 10 microns. In some implementations, the after-stretching length of the flexible circuit 190 is approximately 43 millimeters. In an exemplary flexible circuit with 1,024 conductive traces thereon, the average pitch 210 (including one conductive trace 212 width and one spacing 214 between two adjacent conductive traces, as shown in FIG. 2B) of the flexible circuit 190 traces is approximately 40 microns or less (e.g., 20 microns/trace width and 20 microns/trace spacing, or 18 microns/trace width and 18 microns/trace spacing). These dimensions for the flexible circuit 190 and the pitch 210 are typically smaller than those have previously been used, such as in the industry of printing.

In FIGS. 2A and 2B, the conductive traces 140 on the flexible circuit 190, after being stretched, now align well with the conductive traces 150 on the substrate 130. That is, the pitch of at least some portion of the conductive traces 140 on the flexible circuit 190 matches the pitch of the conductive traces 150 on the substrate 130. For example, the first conductive trace 142 from the leftmost of the flexible circuit 190 now matches up and can be disposed in electrical contact with the corresponding conductive trace 152. Thus, the after-stretching conductive traces 140 on the flexible circuit 190 are capable of carrying output drive signals to the corresponding conductive traces 150 on the substrate 130 if properly connected, without being interrupted for failing to align with the corresponding conductive traces 150.

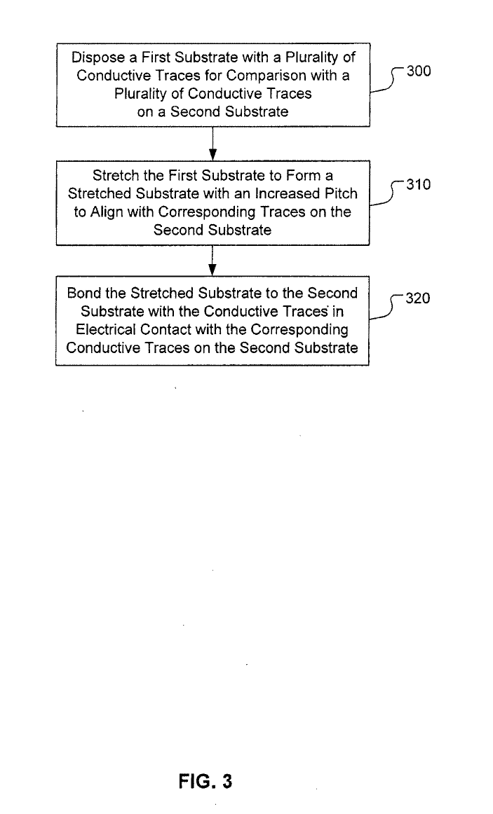

FIG. 3 is a flow chart of an exemplary process for stretching a first substrate with multiple conductive traces thereon, e.g., a flexible circuit, to align with multiple conductive traces on a second substrate, e.g., a silicon die, and bonding the first substrate to the second substrate. The second substrate can be more rigid than the first substrate.

The first substrate is positioned in a way such that the multiple conductive traces on the first substrate can be easily compared with the multiple conductive traces on the second substrate (step 300). In various implementations, the first substrate can be positioned directly adjacent to the second substrate, thereby making it easier to bond the first substrate to the second substrate immediately after aligning the conductive traces. This way the first substrate need not be moved to another location to be bonded after aligning. Optionally, the first substrate can be positioned proximate, but not directly adjacent, to the second substrate despite additional effort needed to move the first substrate before bonding. This stretching process can be observed through a microscope to determine when the stretching is sufficiently complete or it is desirable to stop stretching.

In some implementations, a pattern, e.g., a drawing, dummy substrate or a schematic, that is the same as or identical to the traces to be matched is used in place of the second substrate. This may be useful, for example, if the second substrate will be bonded to the first substrate with the traces on the second substrate facing the traces on the first substrate. A mirror image of the second substrate traces can therefore be used in the comparison step.

After positioning the first substrate adjacent to the second substrate, the first substrate is stretched to form a stretched substrate with an increased pitch (step 310). The increased pitch need not be greater than 40 microns. At least portions of the conductive traces on the stretched substrate align or match up with the corresponding conductive traces on the second substrate. An original length of the first substrate can be between about 0.01% or less to 5% less than an after-stretching length of the first substrate, such as 1% or less. Alternatively, the stretching increases the length of the first substrate by at least 6 to 10 microns. Typically, the pitch of the conductive traces on the first substrate after stretching is from 40 microns to less. An initial pitch of the first substrate can be approximately 36 microns or less. In some embodiments, the original pitch of the conductive traces 140 is approximately 10 microns. The first trace to the last trace tolerance for alignment decreases linearly with reduced pitch for a given length of the first substrate.

The stretched substrate is bonded to the second substrate to cause the electrical traces to be in electrical contact with corresponding conductive traces on the stretched substrate (step 320). The conductive traces on the stretched substrate can be mated with the corresponding traces on the second substrate such that the conductive traces on the stretched substrate are in electrical contact with the corresponding traces on the stretched substrate. Alternatively, the stretched substrate can be bonded to the second substrate by using an epoxy connection, solder connection or ACF (anisotropic conductive film, a thermoset epoxy), accompanied by heating or applying pressure to the stretched substrate. The epoxy can be unfilled or filled, such as a conductive particle filled epoxy. The epoxy can be a spray-on epoxy.

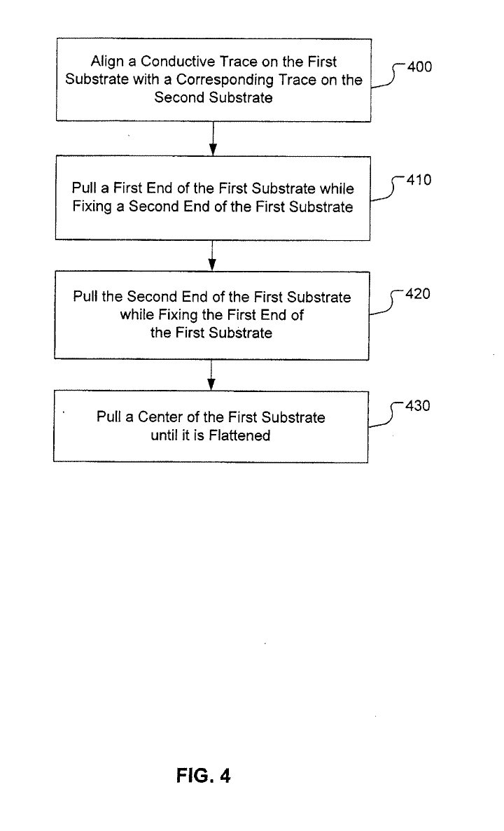

FIG. 4 is a flow chart of an exemplary process for stretching a first substrate to align conductive traces on the first substrate with corresponding conductive traces on a second substrate. First, a conductive trace on the first substrate is aligned with a corresponding trace of the second substrate (step 400). In some embodiments, the conductive traces on the first substrate and the second substrate are traces on a relatively central portion of the substrates. The first and second substrates can be similarly sized, with similarly sized regions of conductive traces. However, in some embodiments, either the first or second substrate is larger than the other substrate or has more traces or a larger conductive area. In an embodiment where the two substrates have the same number of traces, for example, 1024, if the center trace on the first substrate is the 512th trace from the leftmost of the first substrate, the corresponding trace on the second substrate is likewise the 512th from the leftmost of the second substrate when the second substrate is in a position to be bonded to the first substrate. One or both of the first and the second substrates can be temporarily secured in positions adjacent to each other, for example, by pinning, clamping, fastening, taping or adhering the substrate at one or more points, such as at the ends or edges of the substrates.

Subsequent to aligning the selected traces of the first and the second substrates, a first end of the first substrate is pulled while fixing a second end of the first substrate in place (step 410). The second end of the first substrate is an opposite end to the first end of the first substrate. Pulling continues until either the pitch between the traces on each substrate is equal or a specified trace on the first substrate aligns with a corresponding trace on the second substrate. The traces that are matched up with one another after pulling can be, for example, an outermost trace, e.g., the first trace on the left side of each substrate. However, in some embodiments it is desirable to match up traces other than the first trace of each substrate. Similarly, while the pitches of the traces may be equal, in some embodiments, it may be desirable to have a pitch on one substrate that is different from the pitch on the other substrate. By way of illustration, the pitch on one substrate can be a multiple of, for example, two or three times, the pitch on the other.

Similarly, the second end of the first substrate is pulled away from the first end of the first substrate while fixing the first end in place (step 420). Again, pulling continues until either the pitch between the traces on each substrate is equal or a first specified trace on the first substrate aligns with a corresponding first trace on the second substrate. The traces that are matched up with one another after pulling can be, for example, the first trace from the leftmost of each substrate. However, in some embodiments it is desirable to match up traces other than the first trace of each substrate. Similarly, while the pitches of the traces may be equal, in some embodiments, it may be desirable to have the pitch on one substrate that is different from the pitch on the other substrate. The pitch on one substrate can be a multiple of, for example, two or three times, the pitch on the other.

With some substrate materials, when the first substrate is stretched from the ends the substrate tends to bow in the center. To address this problem, the center of the first substrate can be pulled until the substrate is flattened (step 430). The pulling from the center of the substrate can occur simultaneously with the pulling from either end of the substrate. This allows for visual inspection of the process and for proper alignment of traces after stretching or pulling. If the substrate bows during stretching, it can be difficult to determine when pulling should cease.

Portions of the first substrate where the substrate is pulled from can be temporarily secured by, for example, pinning, clamping, taping, fastening, or adhering, and then released by unpinning, unclamping, unfastening, releasing the tape or detaching. Distal portions of the first substrate, e.g., the leftmost and rightmost portions, can be longer than required in the final device to provide areas to be secured and unsecured in the ways disclosed above. The extended portions of the first substrate can be removed after the first substrate is stretched and aligned. Optionally, an additional portion of a suitable material can be attached to each end of the first substrate for securing or pulling the substrate. In some embodiments, the suitable material is sufficiently rigid and does not substantially stretch during the stretching or pulling.

By way of example, an additional portion 160, as shown in FIG. 1, is attached to each of the left and the right sides of the flexible circuit 190. On the additional portions 160, one or more openings 162 are formed for receiving, for example, pins, tacks, bolts, screws, or nails, to temporarily secure the flexible circuit 190. After the flexible circuit 190 is stretched and aligned, the additional portions 160 can be detached from the flexible circuit 190.

A stretched substrate can have slight stretch marks, crimping or tearing, particularly where pins, clamps, tapes, adhesive, tacks, bolts, screws, or nails (that may have been removed) are applied to the substrate or the extended portion or additional portion, or an attachment point of the additional portion to the first substrate, to apply the lateral force to stretch the substrate. Additionally, a tendency of the first substrate, if elastic, to shrink if removed from second substrate is evidence of stretching.

The steps 400-430 disclosed above can be iterated to finally achieve an acceptable alignment between the first and the second substrates. Some of the steps can be skipped while the remaining steps are repeated. By way of illustration, step 400, i.e., aligning a trace of the second substrate with the corresponding trace of the first substrate, can be skipped, while steps 410-430 are still performed.

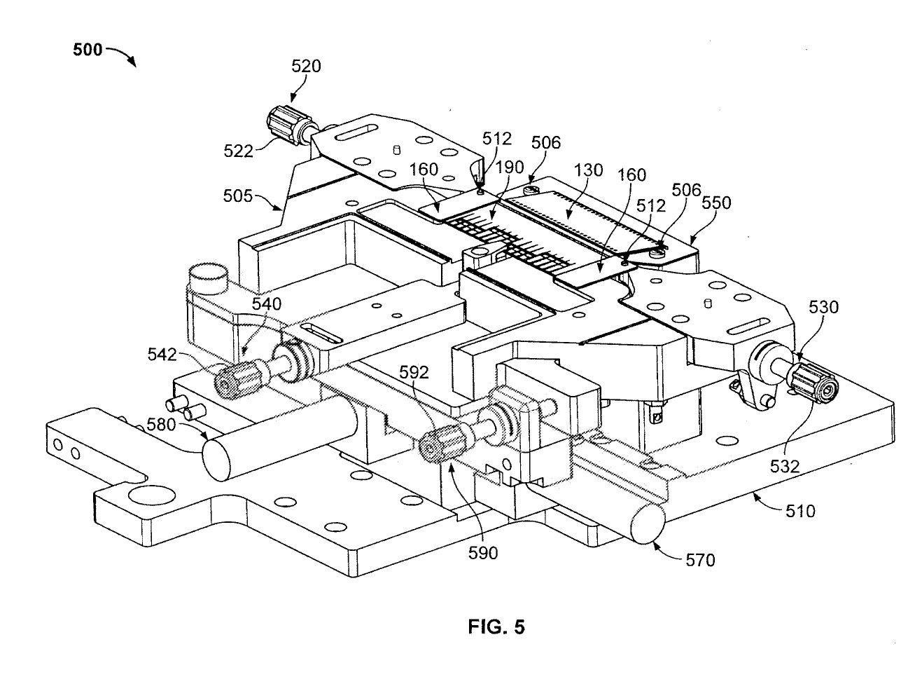

FIG. 5 is a perspective view of a stretching device 500 for stretching a first substrate, e.g., a flexible circuit 190, to align conductive traces thereon with corresponding conductive traces on a second substrate, e.g., a silicon die 130, by pulling the first substrate from its sides. The stretching device 500 includes a base 510 to support a first stretcher, i.e., a left stretcher 520, and a second stretcher, i.e., a right stretcher 530, which are mounted, directly or indirectly, onto the base 510. A third stretcher, such as a center stretcher 540 can also be included in the stretching device 500, and can be mounted, directly or indirectly, onto the base 510. In some embodiments, the right stretcher 510, left stretcher 520 and optional center stretcher 540 are mounted directly or indirectly on a moveable platform 505 and can be moved relative to the moveable platform 505.

The stretching device 500 can further include a platform 550 mounted, directly or indirectly, onto the base 510 such that the second substrate can be temporarily placed and secured on the platform 550. In some embodiments, the platform 550 is a stationary platform and the moveable platform 505 is moveable relative to the stationary platform 550. The moveable platform 505 is configured to receive the first substrate, e.g., flexible circuit 190, which is placed and secured thereon. The stationary platform 550 can be raised above the base 510 with a flat surface on the top for receiving the second substrate. Temporary securing mechanisms, for example, screws, clamps or bolts 506, can be coupled to the stationary platform 550 to temporarily fasten the second substrate thereon. In some embodiments, screws are used merely to guide the second substrate in place and do not secure the second substrate to the stationary platform 550. In various implementations, the stationary platform 550 can also be configured to provide an area for bonding and electronically connecting the second substrate to the first substrate.

An x-axis adjust 570, a y-axis adjust 580, and a theta adjust 590 can also be included as part of the stretching device 500. The x-axis adjust 570 and y-axis adjust 580 cause the moveable platform 505 to move. Thus, moveable platform 505 can be moved relative to stationary platform 550 to provide adjustment of the first substrate position relative to the position of the second substrate.

As previously described, the base 510 functions as a support for all the components directly or indirectly mounted thereon. The base 510 can be made of a plastic or resin, such as polyester, metal, or any suitable material to provide solid support for those components mounted thereon.

The first substrate can be positioned adjacent to the second substrate 130 and temporarily secured by the left stretcher 520 and the right stretcher 530. The first substrate can be secured to the left stretcher 520 and the right stretcher 530 by, for example, screws, bolts, pins, clamps, or like fastening devices. The left stretcher 520 and the right stretcher 530 can be configured to move or slide over the base 510 to pull the first substrate, e.g., flexible circuit 190, along a y-axis that is vertical or orthogonal to conductive traces on the first substrate, thereby stretching the first substrate along the y-axis to align the conductive traces on the first substrate and on the second substrate. The left stretcher 520 and the right stretcher 530 each can be configured to remain still in its position when the other is moving such that at a single time only one end of the first substrate, e.g., flexible circuit 190, is pulled. In addition, the left stretcher 520 and the right stretcher 530 each can be configured to slide in increments of millimeters or less, e.g., in microns, thereby adjusting an extent to which the first substrate is stretched in also millimeters or microns. The side-stretching adjustment can be fine-tuned by rotating knobs 522 and 532 coupled to the left stretcher 520 and the right stretcher 530, respectively.

Additional portions on the first substrate, which are made of a suitable material, can be attached to the first substrate for purposes of being fastened to the left stretcher 520 and the right stretcher 530. Openings or holes can be formed on the additional portions for temporarily receiving, for example, bolts or screws 512 extending from the left stretcher 520 and the right stretcher 530, respectively. After the first substrate is stretched into appropriate alignment with and bonded to the second substrate, the first substrate can be liberated from the bolts or screws 512, and the additional portions can be removed from the first substrate.

The center stretcher 540 can secure and pull the first substrate from its central portion. The first substrate can be temporarily secured to the center stretcher 540 by, for example, clamps or like fasteners. The center stretcher 540 can be mounted, directly or indirectly, onto the base 510. The mounting of the center stretcher 540 can be slidable or movable over the base 510 such that the center stretcher 540 is configured to pull the first substrate along an x-axis that is parallel to conductive traces on the first substrate as well as vertical to the y-axis described previously. Pulling the center stretcher 540 can flatten the first substrate. Moreover, the center stretcher 540 can be configured to slide or move in increments of millimeters or microns, such that the center-stretching can be adjusted in millimeters or microns. The adjustment in distance for center stretching can be made through rotating a knob 542 coupled to the center stretcher 540.

The x-axis adjust 570 can be mounted, directly or indirectly, onto the base 510, and configured to move the moveable platform 505 along the x-axis, which in some embodiments is parallel to a stretching direction of the first substrate, thereby carrying the first substrate along the edge of the second substrate. The y-axis adjust 580 can be mounted, directly or indirectly, onto the base 510, and is configured to move the moveable platform 505 along the y-axis that is vertical or orthogonal to the x-axis, thereby carrying the first substrate, e.g., flexible circuit 190, towards or away from the second substrate. The theta-adjust 590 is configured to rotate the platform 505 to carry the first substrate to an appropriate angle for stretching and aligning the first substrate. A knob 592 can be coupled to the theta-adjust 590 such that an extent of rotating the moveable platform 505 can be fine-tuned by rotating the knob 592. All of the x-axis adjust, y-axis adjust, and theta-adjust can be configured to move the moveable platform 505 in increments of millimeters or less, e.g., in microns.

A microscope (not shown in FIG. 5) can be added to the stretching device 500 to magnify a view of the substrate and conductive traces attached thereon. The microscope provides enhanced precision of aligning the traces. The microscope can be either mounted, directly or indirectly, onto the base 510 of the stretching device 500, or be physically separate from the device 500. The microscope can further include a camera which can transmit an image captured from the microscope to a display for showing the image in magnification.

The use of terminology such as “left” and “right,” “leftmost” and “rightmost,” and “top” and “bottom” throughout the specification or claims serves for illustrative purposes only, to distinguish between various components of the flexible circuit and other elements described herein. The use of these terms does not imply a particular orientation of the flexible circuit. For example, the left side of the flexible circuit described herein can be orientated to the right of the right side of the flexible circuit, and visa versa, depending on whether the flexible circuit is positioned horizontally face-up, horizontally face-down or vertically.

The stretching device 500 shown in FIG. 5 is merely one embodiment of a stretching device and serves only for illustrative purposes. Different embodiments of a stretching device can be used for purposes of this specification and also can be within the scope of the following claims.

What is claimed is:

1. A method of connecting electrical components, comprising:
disposing a first substrate with a plurality of conductive traces for comparison with a plurality of conductive traces on a second substrate;
stretching the first substrate to form a stretched substrate with an increased pitch, wherein at least one increased pitch on the stretched substrate is not greater than 40 microns; and
ceasing stretching when the conductive traces on the stretched substrate align with corresponding conductive traces on the second substrate.

2. The method of claim 1, further comprising electrically connecting conductive traces on the stretched substrate to the conductive traces on the second substrate.

3. The method of claim 1, wherein the first substrate is a flexible circuit and the second substrate is a silicon die.

4. The method of claim 1, further comprising aligning a center conductive trace on the first substrate with a corresponding conductive trace on the second substrate.

5. The method of claim 1, wherein stretching comprises:
pulling a first end of the first substrate while fixing a second end of the first substrate until a first conductive trace on the first substrate aligns with a corresponding first conductive trace on the second substrate; and
pulling the second end of the first substrate while fixing the first end of the first substrate until a second conductive trace on the first substrate aligns with a corresponding second trace on the second substrate.

6. The method of claim 1, further comprising pulling a center of the first substrate, causing the first substrate to flatten.

7. The method of claim 1, further comprising iterating stretching the first substrate until the conductive traces on the first substrate match up with the corresponding conductive traces on the second substrate.

8. The method of claim 1, further comprising:
attaching a portion of suitable material to each of a first end and a second end of the first substrate, wherein the portion of suitable material has one or more openings for receiving a fastener; and
removing the attached portion from each of the first end and the second end of the first substrate after stretching the first substrate.

9. The method of claim 1, wherein stretching includes increasing a length of the first substrate by between 0.01% and 5%.

10. The method of claim 9, wherein stretching includes increasing a length of the first substrate by less than 2%.

11. The method of claim 10, wherein stretching includes increasing a length of the first substrate by less than 1%.

12. The method of claim 1, wherein stretching includes increasing a length of the first substrate by at least 1 micron.

13. The method of claim 12, wherein stretching includes increasing a length of the first substrate by 6 to 10 microns.

14. The method of claim 1, wherein the first substrate before stretching has a pitch not greater than 40 microns.

15. The method of claim 14, wherein the first substrate before stretching has a pitch not greater than 36 microns.

16. The method of claim 15, wherein the first substrate before stretching has a pitch of approximately 10 microns.

17. The method of claim 1, wherein electrically connecting the first substrate to the second substrate includes applying anisotropic conductive film (ACF) to the first substrate.

18. The method of claim 1, wherein electrically connecting the first substrate to the second substrate includes heating and applying pressure to the first substrate.

19. An electronic device, comprising:
a first substrate with a plurality of conductive traces thereon, the first substrate formed of a stretched material, wherein at least one increased pitch on the stretched substrate is not greater than 40 microns; and
a second substrate with the conductive traces thereon aligned and in electrical contact with conductive traces on the first substrate.

20. The device of claim 19, wherein the first substrate is a flexible circuit and the second substrate is a silicon die.

21. A device for stretching a substrate, comprising:
a base;
a first platform mounted on the base for receiving a first substrate thereon;
a second platform mounted on the base for receiving a second substrate thereon; and
a first stretcher and a second stretcher disposed near a first side and a second side of the first platform respectively, and mounted onto the base, wherein:
the first side and the second side are opposite sides of the first platform; and
the first stretcher and the second stretcher are configured to move over the base in increments of millimeters or less to pull the first substrate from a first end and a second end of the first substrate, respectively, along a first axis in opposite directions, such that the first substrate is stretched to align a plurality of conductive traces thereon with corresponding conductive traces on the second substrate.

22. The device of claim 21, wherein the first stretcher and the second stretcher include at least one of a post, pin, a bolt, a clamp, a screw, a tack, or a nail, to temporarily secure a first end and a second end of the first substrate, respectively.

23. The device of claim 21, wherein the first stretcher and the second stretcher each have a knob coupled thereto, wherein the knob can be rotated to move the first stretcher and the second stretcher, respectively.

24. The device of claim 21, further comprising a third stretcher disposed near a third side of the first platform, and mounted onto the base, wherein the third stretcher is configured to move over the base in increments of millimeters or less to pull a center portion along a second axis that is orthogonal to the first axis, such that the first substrate can be stretched along the second axis.

25. The device of claim 24, wherein the third stretcher includes a clamp to temporarily secure a center portion of the first substrate.

26. The device of claim 21, wherein the second platform includes at least one of a pin, a bolt, a clamp, a screw, a tack, screw or a nail, to secure the second substrate supported thereon.

27. The device of claim 21, further comprising an x-axis adjust mounted onto the base and configured to move the first platform along an axis orthogonal to the first axis for carrying the first substrate towards and away from the second platform.

28. The device of claim 21, further comprising a y-axis adjust mounted onto the base and configured to move the first platform along the first axis for carrying the first substrate sideways along the second platform.

29. The device of claim 21, further comprising a theta-adjust mounted onto the base and configured to rotate the first platform for carrying the first substrate to an appropriate angle for stretching, wherein the theta-adjust rotates the first platform relative to the second platform.

30. The device of claim 21, further comprising a microscope for magnifying a view of the first substrate.

31. The device of claim 30, the microscope further comprising:
a camera; and
a display electronically connected with the camera such that the camera can transmit an image captured from the microscope to the display to show the image.

32. A method of connecting electrical components, comprising:
comparing a first plurality of conductive traces on a first substrate with a second plurality of conductive traces on a second substrate, wherein initially traces of the first plurality of conductive traces are not aligned with corresponding traces of the second plurality of traces; and
stretching the first substrate to form a stretched substrate such that the traces of the first plurality of conductive traces on the stretched substrate are aligned with the corresponding traces of the second plurality of traces, and a pitch of the first plurality of conductive traces on the stretched substrate is not greater than 40 microns.

33. The method of claim 32, further comprising electrically connecting at least some of the first plurality of conductive traces on the stretched substrate to at least some of the second plurality of conductive traces on the second substrate.

34. The method of claim 32, further comprising electrically connecting at least some of the first plurality of conductive traces on the stretched substrate to at least some of a third plurality of conductive traces on a third substrate that are aligned with the second plurality of traces.

35. The method of claim 32, wherein stretching includes increasing a length of the first substrate by between 0.01% and 5%.

36. The method of claim 35, wherein stretching includes increasing a length of the first substrate by less than 2%.

37. The method of claim 36, wherein stretching includes increasing a length of the first substrate by less than 1%.

38. The method of claim 32, wherein stretching includes increasing a length of the first substrate by at least 1 micron.

39. The method of claim 38, wherein stretching includes increasing a length of the first substrate by at least 6 to 10 microns.

40. The method of claim 32, wherein the first substrate before stretching has a pitch not greater than 40 microns.

41. The method of claim 40, wherein the first substrate before stretching has a pitch not greater than 36 microns.

42. The method of claim 41, wherein the first substrate before stretching has a pitch of approximately 10 microns.
